(19) United States
(12) Patent Application Publication
(10) Pub. No.: US 2026/0026251 A1
(43) Pub. Date: Jan. 22, 2026

(54) DISPLAY PANEL, MANUFACTURING METHOD THEREFOR, AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Kaijie DENG, Beijing (CN); Xiangdan DONG, Beijing (CN); Wei ZHANG, Beijing (CN); Yu WANG, Beijing (CN); Jianbo LI, Beijing (CN); Jun YAN, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/994,659

(22) PCT Filed: Jan. 2, 2024
(86) PCT No.: PCT/CN2024/070066

§ 371 Date: Jan. 15, 2025

(30) Foreign Application Priority Data
Jan. 31, 2023 (CN) 202310119178.7

(51) Int. Cl. H10K 59/95; H10K 59/12; H10K 59/124

(52) U.S. Cl. CPC H10K 59/95; H10K 59/1201; H10K 59/124

(57) ABSTRACT

The present disclosure provides a display panel. The display panel includes a main body region and a first bonding region, wherein an edge of the main body region is partially inward concaved to form a notch, and the first bonding region is disposed in the notch and is connected to the edge of the main body region.

### CROSS-REFERENCE TO RELATED APPLICATIONS

This application is a U.S. national stage of international application No. PCT/CN2024/070066, filed on Jan. 2, 2024, which claims priority to Chinese Patent Application No. 202310119178.7, filed on Jan. 31, 2023, and entitled “DISPLAY PANEL, MANUFACTURING METHOD THEREOF AND DISPLAY DEVICE,” the disclosures of each are herein incorporated by reference in their entireties.

### TECHNICAL FIELD

The present disclosure relates to the field of display devices, and in particular, to a display panel, a manufacturing method therefor, and a display device.

### BACKGROUND

With the continuous development of display technologies, a display device has a more and more narrow bezel and an increasingly high screen-to-body ratio.

### SUMMARY

Embodiments of the present disclosure provide a display panel, a manufacturing method therefor, and a display device. The technical solutions are as follows.

According to a first aspect, the embodiments of the present disclosure provide a display panel. The display panel includes a main body region and a first bonding region, wherein an edge of the main body region is partially inward concaved to form a notch, and the first bonding region is disposed in the notch and is connected to the edge of the main body region.

In some embodiments, a width of the notch gradually decreases in an inward concaving direction of the edge of the main body region.

In some embodiments, the notch has a shape of a trapezoid.

In some embodiments, the first bonding region is connected to a short base of the trapezoid.

In some embodiments, the display panel includes a plurality of the first bonding regions, and the edge of the main body region is provided with a plurality of the notches, the plurality of first bonding regions being respectively disposed in the plurality of notches.

In some embodiments, the display panel includes a panel body and a back film, wherein a surface of the panel body is attached to the back film, and a surface, away from the panel body, of the back film is provided with a groove, the groove extending along at least a portion of the edge of the main body region, and the groove being at least partially disposed in at least one of the plurality of first bonding regions.

In some embodiments, the display panel further includes a to-be-removed region, wherein the to-be-removed region surrounds the main body region and the first bonding region and is connected to the edge of the main body region and an edge of the first bonding region; and
the groove extends into the to-be-removed region, and a gap is provided between the groove and the edge of the main body region.

In some embodiments, the groove includes a first sidewall close to the main body region and a second sidewall opposite to the first sidewall, wherein the first sidewall extends along a portion of the edge, at a side close to the groove, of the main body region.

In some embodiments, in a length direction of the groove, a width of the groove at different positions is unchanged.

In some embodiments, at least one end of the groove is disposed in at least one of the plurality of notches.

In some embodiments, the back film is provided with a plurality of the grooves, and the plurality of grooves are arranged in one-to-one correspondence to the plurality of first bonding regions; or at least one of the plurality of grooves is disposed in multiple of the plurality of first bonding regions.

In some embodiments, the first bonding region is disposed at each of two opposite sides of the main body region.

In some embodiments, the panel body is provided with an alignment mark disposed in the to-be-removed region; wherein
the alignment mark is disposed in the groove; or
the back film is further provided with an alignment slot formed in the to-be-removed region, and the alignment mark is disposed in the alignment slot.

In some embodiments, the display panel further includes a second bonding region, wherein the second bonding region is disposed outside the notch and connected to the edge of the main body region.

In some embodiments, the second bonding region and the first bonding region are disposed at two opposite sides of the main body region.

According to a second aspect, the embodiments of the present disclosure further provide a method for manufacturing a display panel. The method includes:
providing a to-be-cut display panel, wherein the display panel includes a main body region. a first bonding region, and a to-be-removed region, the first bonding region being connected to an edge of the main body region, and the to-be-removed region surrounding the main body region and the first bonding region and being connected to the edge of the main body region and an edge of the first bonding region, and
removing the to-be-removed region, and forming an inward concave notch on the edge of the main body region, the first bonding region being disposed in the notch.

In some embodiments, the display panel includes a panel body and a back film, a surface of the panel body is attached to the back film, and prior to removing the to-be-removed region, the method further includes:
forming a groove at a surface, away from the panel body, of the back film, wherein the groove extends along at least a portion of the edge of the main body region and is at least partially disposed in the first bonding region, and a gap is provided between the groove and the edge of the main body region.

According to a third aspect, the embodiments of the present disclosure further provide a display device. The display device includes any display panel as defined in the foregoing aspect

### BRIEF DESCRIPTION OF THE DRAWINGS

To describe the technical solutions of the embodiments of the present disclosure more clearly, the following briefly describes the accompanying drawings required for describing the embodiments. Apparently, the accompanying drawings in the following description show only some embodiments of the present disclosure, and a person of ordinary skill in the art may still derive other drawings from these accompanying drawings without creative efforts.

FIG. 1 is a partial schematic structural diagram of a display device according to some embodiments of the present disclosure,

FIG. 2 is a schematic diagram of a display panel according to some embodiments of the present disclosure;

FIG. 3 is a partial schematic structural diagram of a display panel according to some embodiments of the present disclosure;

FIG. 4 is a schematic structural diagram of a display panel according to some embodiments of the present disclosure;

FIG. 5 is a side view of a display panel according to some embodiments of the present disclosure;

FIG. 6 is a sectional view of a display panel according to some embodiments of the present disclosure;

FIG. 7 is a partial schematic diagram of a display panel according to some embodiments of the present disclosure;

FIG. 8 is a partial schematic structural diagram of a display panel according to some embodiments of the present disclosure;

FIG. 9 is a partial schematic structural diagram of a display panel according to some embodiments of the present disclosure;

FIG. 10 is a partial schematic structural diagram of a display panel according to some embodiments of the present disclosure;

FIG. 11 is a partial schematic structural diagram of a display panel according to some embodiments of the present disclosure;

FIG. 12 is a partial schematic structural diagram of a display panel according to some embodiments of the present disclosure;

FIG. 13 is a schematic structural diagram of a display panel according to some embodiments of the present disclosure;

FIG. 14 is a schematic structural diagram of a display panel according to some embodiments of the present disclosure,

FIG. 15 is a partial schematic structural diagram of a display panel according to some embodiments of the present disclosure;

FIG. 16 is a partial schematic structural diagram of a display panel according to some embodiments of the present disclosure;

FIG. 17 is a partial schematic structural diagram of a display panel according to some embodiments of the present disclosure;

FIG. 18 is a schematic structural diagram of a display panel according to some embodiments of the present disclosure; and

FIG. 19 is a flowchart of a method for manufacturing a display panel according to some embodiments of the present disclosure.

### DETAILED DESCRIPTION

To make the objectives, technical solutions, and advantages of the present disclosure clearer, the embodiments of the present disclosure are further described hereinafter in detail with reference to the accompanying drawings.

Unless otherwise defined, the technical terms and scientific terms used herein have the same meaning as how they are generally understood by those of ordinary skill in the art to which the present disclosure belongs. Terms such as “first,” “second,” and “third” used in the specification and the claims of the present disclosure are only used to distinguish different components and do not intend to indicate any order, number, or importance. Similarly, “one,” “a,” and similar terms also do not represent a quantity limitation, but instead represent “at least one.” Terms such as “comprise” or “include” means that an element or object in front of “comprise” or “include” covers elements or objects listed behind “comprise” or “include” or their equivalents, but do not exclude other elements or objects. Terms such as “connection” or “connected” are not limited to a physical or mechanical connection, but may include an electrical connection directly or indirectly. “Up,” “down,” “left”, “right,” and the like are only used to represent a relative position relationship. The relative position relationship may be correspondingly changed in the case that the absolute locations of described objects are changed.

In a display device according to the related art, a bonding region is disposed at an edge of a display panel, and the bonding region is bent to a back surface of the display panel to achieve fixing, to improve the screen-to-body ratio. In the case that the bonding region is bent, it can be seen, when observing vertically from a front surface of the display panel, that the bonding region protrudes outward relative to the display panel, which adversely affects the subsequent assembling of the display panel and the screen-to-body ratio of the display device.

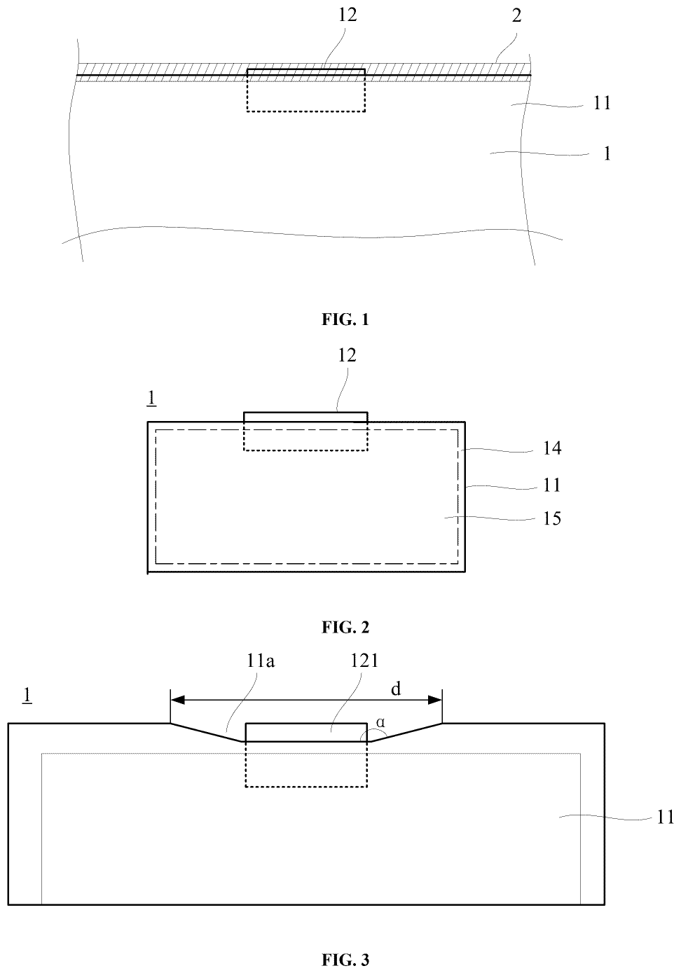

FIG. 1 is a partial schematic structural diagram of a display device according to some embodiments of the present disclosure. The display device includes, but not limited to, a mobile phone, a tablet computer, or a smartwatch. The embodiments of the present disclosure are described by taking an example of a mobile phone. As shown in FIG. 1, the display device includes a display panel 1 and a shielding structure 2. The display panel includes a main body region 11 and a bonding region 12. The bonding region 12 is connected to an edge, at a side, of the main body region 11. The bonding region 12 is bent to a back surface of the display panel 1.

In the embodiments of the present disclosure, a front surface of the display panel is a surface configured for displaying of the display panel, and the back surface is a surface opposite to the front surface. In some embodiments, the shielding structure 2 herein is any structure that is capable of shielding light. In some embodiments, the shielding structure 2 is a frame. For a display device with a cover plate disposed on the front surface of a display panel, the shielding structure 2 is an opaque structure, at an edge, of the cover plate, such as a light-shielding layer disposed at the edge of the cover plate.

FIG. 2 is a schematic diagram of a display panel according to some embodiments of the present disclosure. As shown in FIG. 2, according to the need for displaying a picture, the display panel 1 is further divided into a display region 15 and a non-display region 14 disposed outside the display region 15. In the embodiments of the present disclosure, the main body region 11 includes the display region 15 and a part of the non-display region 14. The part of the non-display region 14 is adjacent to the display region 15. The bonding region 12 includes another part of the non-display region 14. The shielding structure 2 is configured to shield the non-display region 14 of the display panel 1. As can be seen from FIG. 1 and FIG. 2, in the case that the bonding region 12 is bent, the bonding region 12 protrudes outward with respect to an edge of the main body region 11. The bonding region 12 has a minimum bending radius. In the case that the bending radius of the bonding region 12 at a bending state is less than the minimum bending radius, the bonding region 12 is susceptible to a high risk of damage. Therefore, the bending radius of the bonding region 12 is usually greater than or equal to the minimum bending radius However, a larger bending radius of the bonding region 12 results in a larger outward protruding distance of the bonding region 12 relative to the edge of the main body region 11.

On a side, close to the bonding region 12, of the main body region 11, in addition to shielding the non-display region 14 in the main body region 11, the shielding structure 2 further needs to shield a part of the bonding region 12 that protrudes relative to the edge of the main body region 11. As a result, a shielding range of the shielding structure 2 is expanded, affecting the screen-to-body ratio of the display panel. In the case of the display device falling or in other cases, the outward protruded portion of the bonding region 12 is likely to collide with a housing or other structures (such as a middle frame) of the display device, resulting in increased stress inside the bonding region 12 and an increased risk of damage.

In the production process of the display device, upon the bonding region 12 being bent to the back surface of the display panel 1, the bonding region 12 protrudes outward, not only affecting the appearance but also likely adversely impacting the transfer and subsequent processing of the display panel 1, such as, the outward protruded portion is in contact with another object, thereby increasing stress inside the bonding region 12 and causing damage to the bonding region 12.

FIG. 3 is a partial schematic structural diagram of a display panel according to some embodiments of the present disclosure. The technical solution reduces an outward protruding distance of the bonding region relative to the display panel. As shown in FIG. 3, the display panel is provided with a main body region 11 and a first bonding region 121. An edge of the main body region 11 is partially inward concaved to form a notch 11a, and the first bonding region 121 is disposed in the notch 11a connected to the edge of the main body region 11.

In the embodiments, the notch 11a is formed at the edge of the main body region 11, and the first bonding region 121 is disposed in the notch 11a, such that the first bonding region 121 moves in the inward concaving direction of the edge of the main body region 11 by a distance. In the case that the first bonding region 121 is bent, the outward protruding distance of the first bonding region 121 relative to the edge, except the portion of the notch 11a, of the main body region 11 is reduced, or even the outward protruding distance of the first bonding region 11 is reduced to make the first bonding region 121 flush with the edge, except the portion of the notch 11a, of the main body region 11, thereby avoiding the impact of the protrusion of the first bonding region 121 on the subsequent processing of the display panel 1, and facilitating increasing the screen-to-body ratio of the display device.

As shown in FIG. 3, the notch 11a is within the non-display region 14, that is, an inward concaved depth of the edge of the main body region 11 is not large enough to make the edge reach the display region 15. That is, an edge of the display region 15 (i.e., a boundary between the display region 15 and the non-display region 14) is not concaved inward the display region 15, so as to allow the display region 15 to keep the original shape. In the embodiments of the present disclosure, the provided accompanying drawings are only illustrative and do not represent actual sizes or forms. The depth by which the edge of the main body region 11 is inward concaved is selected according to a specific requirement.

As shown in FIG. 3, a width of the notch 11a gradually decreases in an inward concaving direction of the edge of the main body region 11. A position with the maximum width d of the notch 11a is labeled in FIG. 3.

In some embodiments, the edge of the main body region 11 includes at least one side, which is straight or curved. In some embodiments, the main body region 11 has a shape of a rectangle, the edge of the main body region 11 includes four straight sides, and the notch 11a is disposed on one specific straight side of the main body region 11. The width of the notch 11a is a width in a direction parallel to the specific straight side of the main body region 11. Specifically, in the case that a series of straight lines parallel to each other and parallel to the specific straight side of the main body region 11 (specifically parallel to a portion, except the portion of the notch 11a, of the specific straight side of the main body region 11) are drawn at the notch 11a, each straight line has two intersections with the concaved portion of the specific straight side of the main body region 11, such that a series of line segments parallel to each other are acquired and the lengths of these line segments are the width of the notch 11a. In some other embodiments, for a display panel in a display device like a smartwatch, the main body region 11 has a shape of a circle. The edge of the main body region 11 is a curved side. The notch 11a is disposed on the curved side of the main body region 11. The width of the notch 11a is a width in a circumferential direction. Specifically, in the case that a series of concentric circles are drawn with the center of the curved side as the circle center, each of these circles has two intersections with the concaved portion of the curved side, such that a series of arcs are acquired and the lengths of these arcs are the width of the notch 11a.

By setting the width of the notch 11a gradually decreasing in the inward concaving direction of the edge of the main body region 11, the stress at the portion, i.e., at the notch 11a, of the edge of the main body region 11 is reduced, thereby avoiding stress concentration. In some embodiments of the present disclosure, the notch 11a has a shape of a rectangle. In other words, the portion, at the notch 11a, of the edge of the main body region 11 forms two right angles. Stress is large at the right angles. The stress at the right angles is further increased especially in the case that the first bonding region 121 is bent, causing an increased risk of the display panel 1 cracking at the position of the right angles.

As shown in FIG. 3, the notch 11a has a shape of a trapezoid. In other words, the portion, at the notch 11a, of the edge of the main body region 11 is bent into two obtuse angles, such that stress is reduced. In addition, the edge of the main body region 11 is planar and straight, which facilitates the processing of the main body region 11 and manufacturing of the display panel.

In some embodiments, the obtuse angles α between the waists and the short base of the trapezoid range from 155° to 165°. The obtuse angles between the waists and the short base of the trapezoid are set relatively large, which helps to reduce stress at connection positions between the waists and the short base.

In some embodiments, the connection positions between the short base and the waists of the trapezoid are smoothly transitioned, i.e., rounded angles are formed at the connection positions, which helps to further reduce stress in the display panel.

As shown in FIG. 3, the first bonding region 121 is connected to the short base of the trapezoid. The distance between the short base of the trapezoid and a long base of the trapezoid is the depth of the notch 11a, i.e., the depth by which the edge of the main body region 11 is concaved.

The portion, at the notch 11a, of the edge of the main body region 11 includes three sections, which respectively correspond to the short base and the two waists of the trapezoid that are connected to the short base of the trapezoid, i.e., connected to one section, that corresponds to the short base of the trapezoid, of the three sections. In some embodiments, a length of one side, connected to the main body region 11, of the first bonding region 121 is less than or equal to the length of the short base of the trapezoid, i.e., gaps are provided between the first bonding region 121 and both the waists of the trapezoid, such that in the case that the first bonding region 121 is bent, the two waists of the trapezoid are kept from being pulled, thereby avoiding an increase in the stress in the display panel.

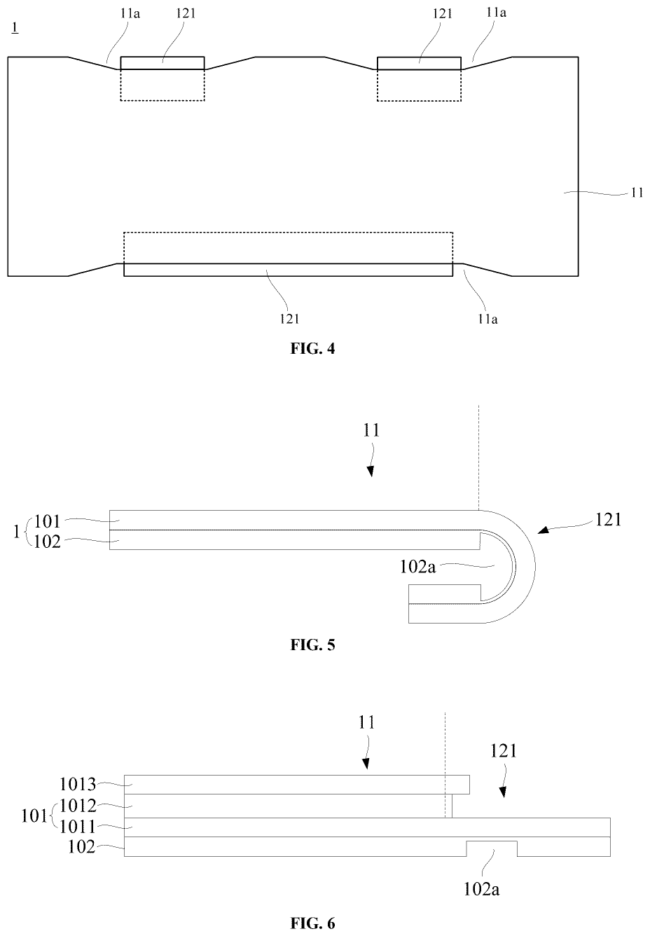

FIG. 4 is a schematic structural diagram of a display panel according to some embodiments of the present disclosure. As shown in FIG. 4, the display panel includes a plurality of first bonding regions 121, and the edge of the main body region 11 is provided with a plurality of notches 11a, the plurality of first bonding regions 121 being respectively disposed in the plurality of notches 11a.

For a display panel with a small area, the normal operation of the display panel is usually ensured by disposing one bonding region. For a display panel with a large area, a circuit structure in the display panel is more complex, and more wires that extend to a bonding region to achieve connections to other external structures (such as a flexible circuit board) are necessary, the wires including but not limited to a power lead, a touch signal line, a data line, or a gate signal line. In some embodiments, in a flexible multi-layer on cell (FMLOC) display panel, a touch structure is formed on an outer side of a thin film encapsulation layer of the display panel. A touch signal line or the like of the touch structure needs to be led out to a bonding region to achieve a connection to the flexible circuit board.

In the case that all these wires extend into the same bonding region, the difficulty of routing is increased, and a wire at a position far away from the bonding region in the main body region 11 needs to be with a large length so as to extend into the bonding region, resulting in increased resistance of the wire, which adversely affects the transmission of an electrical signal. Capacitance is further formed between the wires and between the wire and another part in the circuit structure, which also adversely affects an electrical signal, thereby affecting the performance of the display panel, e.g., affecting touch operations. In the embodiments, a plurality of first bonding regions 121 are disposed. In this way, the wire in the display panel is capable of extending into the nearest first bonding region 121, thereby reducing the length of the wire, and avoiding various adverse impacts caused by excessively long wires.

In some embodiments, the plurality of first bonding regions 121 are distributed on the same side of the main body region 11, or distributed on different sides of the main body region 11. In some embodiments, the first bonding region 121 is disposed at each of two opposite sides of the main body region 11. The display panel usually bends more easily along a bending line in a specific direction and bends hardly along a bending line perpendicular to the specific direction. Concerning this characteristic, the first bonding region 121 is disposed at each of two opposite sides of the main body region 11, such that a sufficient number of first bonding regions 121 are disposed by fully utilizing space, and bending lines of all the first bonding regions 121 are parallel to each other and are all set in the specific direction, thereby facilitating the bending of the first bonding regions 121.

FIG. 5 is a side view of a display panel according to some embodiments of the present disclosure. As shown in FIG. 5, the display panel includes a panel body 101 and a back film 102. A surface of the panel body 101 is attached to the back film 102. In some embodiments, the back film 102 is bonded to a backplate 1011. The back film 102 is configured to provide protection and support for the panel body 101. In some embodiments, the back film 102 is made of a flexible material, such as thermoplastic resin, which specifically includes polyethylene terephthalate, polyurethane, or the like. In some embodiments, the thickness of the back film 102 ranges from 10 μm to 50 μm, such as 13 μm.

A surface, away from the panel body 101, of the back film 102 is provided with a groove 102a. The groove 102a extends along at least a portion of the edge of the main body region 11. and the groove 102a is at least partially disposed in the first bonding region 121

FIG. 6 is a sectional view of a display panel according to some embodiments of the present disclosure, in which the first bonding region 121 of the display panel has not been bent. As shown in FIG. 6, the panel body 101 includes the backplate 1011 and a circuit structure and a light-emitting layer 1012 that are disposed on a surface of the backplate 1011. The light-emitting layer 1012 is connected to the circuit structure to emit light under the drive of the circuit structure. In some embodiments, the light-emitting layer 1012 is completely disposed in the main body region 11, or is mainly disposed in the main body region 11 and has an edge part disposed in the first bonding region 121. In some embodiments, the backplate 1011 is a flexible backplate. In some embodiments, the backplate 1011 is made of polyimide PI. In some embodiments, a thickness of the backplate 1011 ranges from 50 μm to 100 μm, such as 75 μm.

In some embodiments, the light-emitting layer 1012 includes a plurality of light-emitting units. In some embodiments, the light-emitting unit is an organic light-emitting diode (OLED). In some embodiments, during the manufacturing process of the display panel, a protective film 1013 is further disposed on the light-emitting layer 1012 to protect the light-emitting layer 1012. In the case that the manufacturing is completed, the protective film 1013 is then peeled off. The back film 102 is disposed on the other surface of the backplate 1011.

The groove 102a is provided in the surface, away from the panel body 101, of the back film 102, such that the structural strength of the back film 102 is reduced, making the back film 102 more easily bend at the position of the groove 102a. The groove 102a is at least partially disposed in the first bonding region 121, which facilitates the bending of the first bonding region 121.

As shown in FIG. 5, in some embodiments, the depth of the groove 102a is less than the thickness of the back film 102. In some other embodiments, the depth of the groove 102a is the same as the thickness of the back film 102. That is, the groove 102a penetrates the back film 102 in the thickness direction.

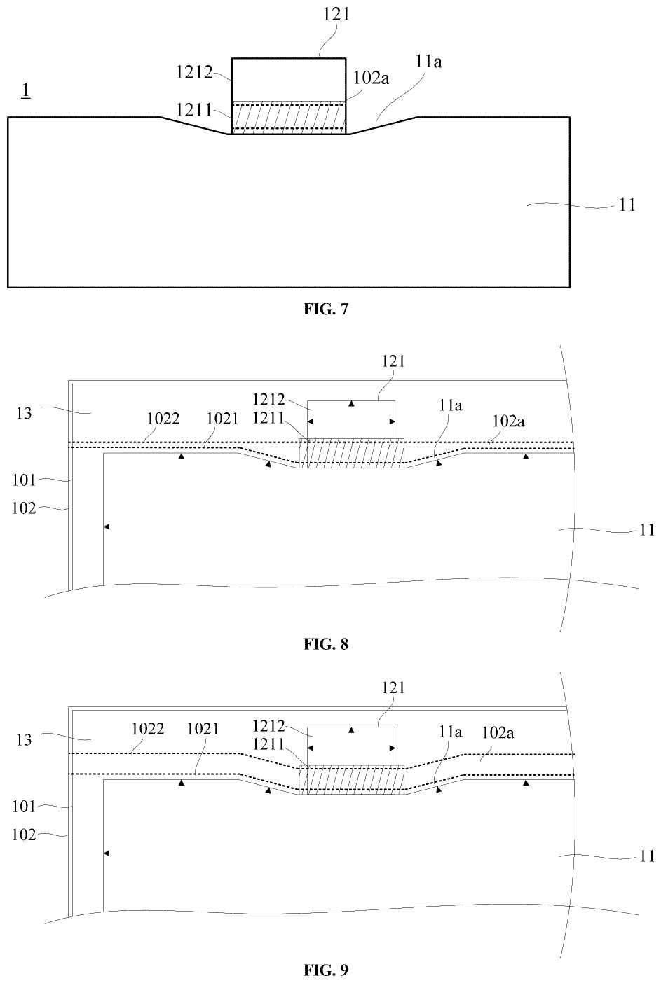

The bonding region usually includes a bending region and a pin region that are connected. In some embodiments, FIG. 7 is a partial schematic diagram of a display panel according to some embodiments of the present disclosure, in which the first bonding region 121 has not been bent. As shown in FIG. 7, the first bonding region 121 includes a bending region 1211 and a pin region 1212. The bending region 1211 is connected to the main body region 11. The pin region 1212 is disposed on a side, away from the main body region 11, of the bending region 1211 and is connected to the bending region 1211. The bending region 1211 easily deforms to bend. A plurality of pins are disposed in the pin region 1212. The pins are connected to signal lines extending to the first bonding region 121. The pins are used for achieving the connection to other structures, such as a circuit board. In some embodiments, a lead region is further included. The lead region is connected between the main body region 11 and the bending region 1211. Leads in the display panel converge in the lead region and then extend to the pin region 1212 to be connected to the pins.

The circuit structure, the light-emitting layer 1012, and the like in the panel body 101 all include multiple film layers. The film layers are formed on the backplate 1011 layer by layer through various processes. To make the display panel easily bend, in the process of manufacturing the panel body 101, part of the film layers in the bending region 1211 is removed through processes such as etching, to make the thickness, at the bending region 1211, of the panel body 101 less than a thickness at another position, such as less than the thickness of the display region 15. In some embodiments, an orthographic projection of the groove 102a of the back film 102 on the bending region 1211 is within the bending region 1211, and the width of the groove 102a is less than or equal to the width of the bending region 1211. In some embodiments, the width of the groove 102a is less than the width of the bending region 1211 by at least 0.15 mm. A contour of the groove 102a is shown by dash lines in FIG. 7. The orthographic projection of the groove 102a on the bending region 1211 is within the bending region 1211, and the width of the groove 102a is less than the width of the bending region 1211.

FIG. 8 is a partial schematic structural diagram of a display panel according to some embodiments of the present disclosure. As shown in FIG. 8, the display panel includes a to-be-removed region 13. The to-be-removed region 13 surrounds the main body region 11 and the first bonding region 121, and the to-be-removed region 13 is connected to the edge of the main body region 11 and an edge of the first bonding region 121. FIG. 8 shows a boundary between the to-be-removed region 13 and the main body region 11 and a boundary between the to-be-removed region 13 and the first bonding region 121 through black triangles.

In the processing process of the display panel, the to-be-removed region 13 is eventually removed. In other words, the display panel shown in FIG. 8 is unfinished. Upon the to-be-removed region 13 of the display panel being removed, the structure is as shown in FIG. 7. Prior to cutting, the area of the panel body 101 is usually slightly smaller than the area of the back film 102. Certainly, in some embodiments, the panel body 101 and the back film 102 completely overlap before cutting, that is, the area of the panel body 101 is the same as the area of the back film 102.

As shown in FIG. 8, in the display panel, the groove 102a in the back film 102 extends into the to-be-removed region 13, and a gap is provided between the groove 102a and the edge of the main body region 11.

The boundary between the to-be-removed region 13 and the main body region 11 and the boundary between the to-be-removed region 13 and the first bonding region 121 are cut lines for cutting the display panel The groove 102a is completely disposed outside the main body region 11, and a gap is provided between the groove 102a and the edge of the main body region 11, such that during cutting along the boundary between the to-be-removed region 13 and the main body region 11, the groove 102a is kept from being cut. The display panel has different thicknesses in the groove 102a and outside the groove 102a, stress distributions are also different, and the difficulty levels of cutting are different. During cutting, in the case that the boundary between the to-be-removed region 13 and the main body region 11 is cut, the precision of cutting is affected, and the film layers of the display panel are likely stripped from each other, such as the panel body 101 and the back film 102 being stripped from each other.

As shown in FIG. 8, in the boundary between the to-be-removed region 13 and the first bonding region 121, a portion, passing through the groove 102a, of the boundary is perpendicular to an extension direction of the groove 102a. The boundary between the to-be-removed region 13 and the first bonding region 121 inevitably includes a portion passing through the groove 102a. Passing through the groove herein means that an orthographic projection of the portion of the boundary on the surface of the back film 102 intersects the groove 102a. The cut lines are perpendicular to the extension direction of the groove 102a at this position, such that the risk that the film layers of the display panel are stripped from each other during cutting along the boundary between the to-be-removed region 13 and the first bonding region 121 is reduced.

As shown in FIG. 8, the groove 102a includes a first sidewall 1021 and a second sidewall 1022. The first sidewall 1021 is close to the main body region 11, and the second sidewall 1022 is opposite to the first sidewall 1021. The first sidewall 1021 extends along a portion of the edge, at a side close to the groove 102a, of the main body region 11.

The first sidewall 1021 extends along a portion of the edge of the main body region 11, such that the groove 102a is kept from entering the main body region 11 and overlapping the cut lines.

The width of the gap between the groove 102a and the edge of the main body region 11 is the distance between the first sidewall 1021 and the edge, at the side close to the groove 102a, of the main body region 11. In some embodiments, the width of the gap is constant. That is, the width of the gap remains the same at different positions.

As shown in FIG. 8, in some embodiments, the second sidewall 1022 of the groove 102a is parallel to a portion, except the portion of the notch 11a, of the edge of the main body region 11. The width of a portion, that extends out of the notch 11a from inside the notch 11a, of the groove 102a gradually changes.

FIG. 9 is a partial schematic structural diagram of a display panel according to some embodiments of the present disclosure. As shown in FIG. 9, in some other embodiments, the second sidewall 1022 of the groove 102a also extends along at least a portion of the edge of the main body region 11, and in a length direction of the groove 102a, the width of the groove 102a remains the same at different positions. Because the width remains the same, during the formation of the groove 102a in the back film 102, the width of the groove 102a is better monitored, making the manufacturing more convenient.

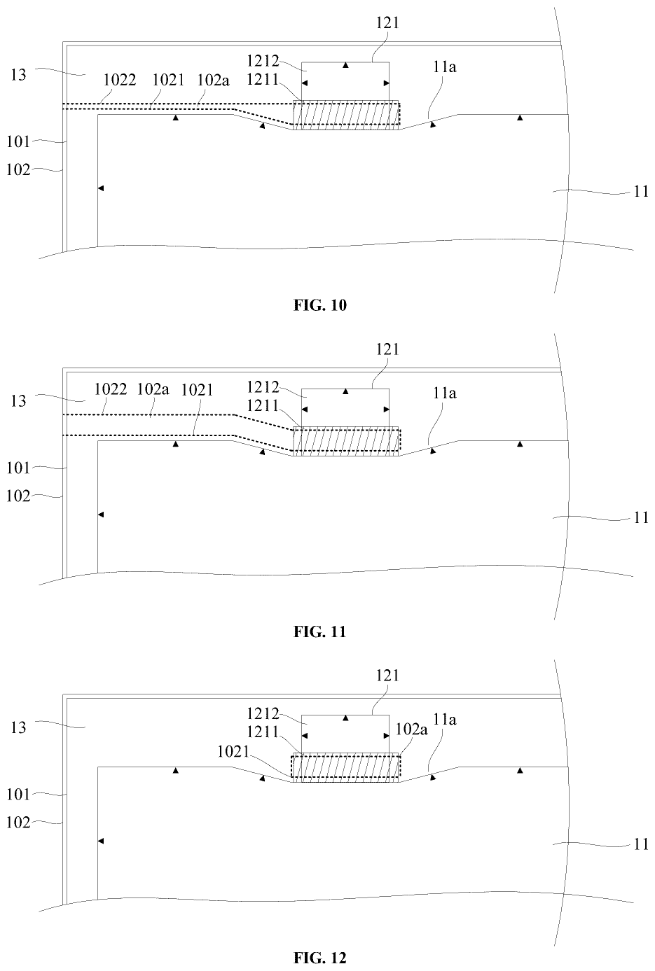

In the embodiments shown in FIG. 8 and FIG. 9, both two ends of the groove 102a extend out of the notch 11a. In some embodiment, the two ends of the groove 102a even further extend to an edge of the back film 102. In some other embodiments, at least one end of the groove 102a is disposed in the notch 11a. That is, one end or two ends of the groove 102a do not extend out of the notch 11a. In some embodiments, in the display panel shown in FIG. 10 and FIG. 11, one end of the groove 102a extends to the edge of the back film 102, and the other end of the groove 102a is disposed in the notch 11a.

FIG. 12 is a partial schematic structural diagram of a display panel according to some embodiments of the present disclosure. As shown in FIG. 12, in the embodiments, the length of the groove 102a is less than the width of the notch 11a, and both the two ends of the groove 102a are disposed in the notch 11a. During the cutting of the display panel, the portion, extending into the to-be-removed region 13, of the groove 102a is completely cut. Therefore, it is also workable to dispose the groove 102a only in the notch 11a. That both the two ends of the groove 102a being disposed in the notch 11a described herein refers to that at least two ends of the first sidewall 1021 of the groove 102a are disposed in the notch 11a. The second sidewall 1022 of the groove 102a is in the notch 11a or outside the notch 11a, and whether the second sidewall 1022 is in the notch 11a depends on a relationship between the inward concaved depth of the edge of the main body region 11 and an distance between the first sidewall 1021 and the edge of the main body region 11. In the case that the inward concaved depth of the edge of the main body region 11 is less than the distance between the first sidewall 1021 and the edge of the main body region 11, the first sidewall 1021 is disposed outside the notch 11a, otherwise, the first sidewall 1021 is disposed in the notch 11a.

In some embodiments, the length of the groove 102a is less than the length of the short base of the trapezoid. In this way, even if the groove 102a does not have a structure with an irregular shape as shown in FIG. 10 or FIG. 11, the groove 102a is still kept from overlapping the edge of the main body region 11, making the manufacturing more convenient.

As shown in FIG. 12, end portions of the groove 102a extend beyond the bending region 1211 of the first bonding region 121. In some embodiments, the end portion of the groove 102a at least extends beyond an edge of the bending region 1211 by 0.5 mm. The purpose is to ensure that upon the cutting being completed, two ends of the groove 102a in the first bonding region 121 are in communication, and penetrate the first bonding region 121.

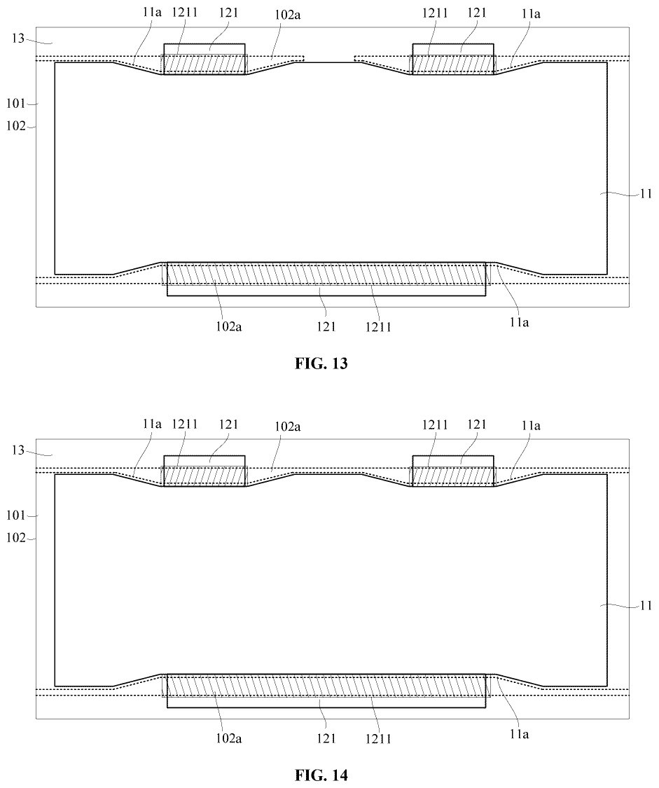

FIG. 13 is a schematic structural diagram of a display panel according to some embodiments of the present disclosure. As shown in FIG. 13, in the display panel, the back film 102 is provided with a plurality of grooves 102a. The plurality of grooves 102a are arranged in one-to-one correspondence to the plurality of first bonding regions 121. The grooves 102a are disposed in a one-to-one correspondence manner, such that the width of each groove 102a is set based on a specific condition of each first bonding region 121 (such as the width of the bending region 1211 of the first bonding region 121,) making the design more flexible.

In some embodiment, in the case that the plurality of grooves 102a are disposed, the plurality of grooves 102a is distributed on the same side of the main body region 11, or distributed on two opposite sides of the main body region 11. In addition, in some embodiments, two or more grooves 102a are distributed on the same side of the main body region 11.

FIG. 14 is a schematic structural diagram of a display panel according to some embodiments of the present disclosure. As shown in FIG. 14, at least one groove 102a is disposed in multiple first bonding regions 121. In other words, two or more first bonding regions 121 are distributed on one side of the main body region 11. On this side of the main body region 11, the same groove 102a extends into the two or more first bonding regions 121. In this way, during processing, it is only necessary to provide one groove 102a corresponding to the multiple first bonding regions 121 on one side of the main body region 11, making the manufacturing more convenient. In addition, in the case that multiple first bonding regions 121 are arranged on one side of the main body region 11, the width of each of the multiple first bonding regions 121 is designed to be small. In some embodiments, both the widths of two first bonding regions 121 disposed on an upper side of the main body region 11 in FIG. 14 are less than the width of a first bonding region 121 disposed on a lower side of the main body region 11. A first bonding region 121 with a small width is more easily to be bent, and generates smaller stress.

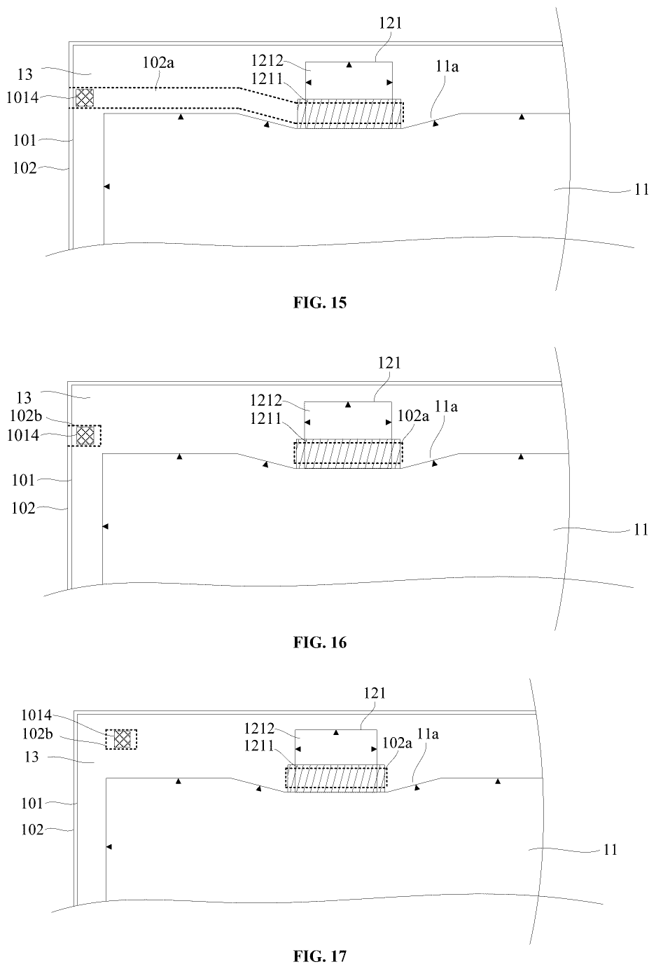

FIG. 15 is a partial schematic structural diagram of a display panel according to some embodiments of the present disclosure. As shown in FIG. 15, an alignment mark 1014 is provided on the panel body 101, and the alignment mark 1014 is disposed in the to-be-removed region 13. The alignment mark 1014 is disposed in the groove 102a.

In the panel body 101, the alignment mark 1014 is usually provided at a position close to an edge. During cutting, the alignment mark 1014 facilitates the positioning of a cutting device, thereby improving the precision of cutting. The alignment mark 1014 is disposed in the to-be-removed region 13, and therefore is removed in the case that the cutting of the display panel is completed.

Although the back film 102 is possible to be set as transparent, the back film 102 has a certain thickness, which has an impact on the precision of positioning due to refraction or other reasons. The groove 102a is aligned with the alignment mark 1014, such that the alignment mark is observed from the groove 102a, to facilitate capture by a camera or other optical devices, thereby improving the precision of positioning.

FIG. 16 is a partial schematic structural diagram of a display panel according to some embodiments of the present disclosure. As shown in FIG. 16, the back film 102 is further provided with an alignment slot 102b, the alignment slot 102b is formed in the to-be-removed region 13, and the alignment mark 1014 is disposed in the alignment slot 102b.

For different panel bodies 101, the alignment mark 1014 is possible to be disposed at different positions, such that the alignment mark 1014 is possible to be outside the groove 102a. The position of the alignment slot 102b is designed based on the position of the alignment mark 1014, such that the alignment mark 1014 is exposed from the alignment slot 102b, thereby improving the precision of positioning. In some embodiments, the alignment slot 102b is disposed at an edge of the back film 102, such as, at a position shown in FIG. 16. In some other embodiments, a gap is provided between the alignment slot 102b and the edge of the back film 102, such as the gap as shown in FIG. 17.

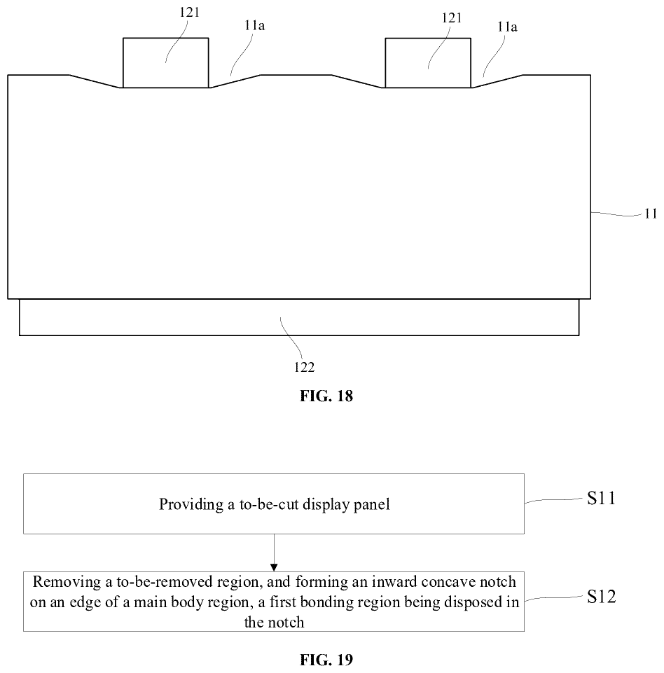

FIG. 18 is a schematic structural diagram of a display panel according to some embodiments of the present disclosure. As shown in FIG. 18, the display panel further includes a second bonding region 122, the second bonding region 122 is disposed outside the notch 11a, and the second bonding region 122 is connected to the edge of the main body region 11. In other words, in the case that the display panel is provided with a plurality of bonding regions, each bonding region is disposed in the notch 11a, or only some of the bonding regions are disposed in the notches 11a, to meet the process requirements of different display panels.

As shown in FIG. 18, the second bonding region 122 and the first bonding region 121 are disposed at two opposite sides of the main body region 11.

The first bonding region 121 and the second bonding region 122 are respectively disposed at two sides, such that only one side of the main body region 11 needs to be provided with the notch 11a.

Especially for some bonding regions with large widths, such as the second bonding region 122 shown in FIG. 18 which has a width nearly the same as the length of the edge, close to the second bonding region 122, of the main body region 11, in the case that the second bonding region 122 is bent, nearly one entire side of the display panel is bent. Therefore, such bonding regions do not need a notch 11a.

The embodiments of the present disclosure further provide a display device. The display device includes any display panel shown in FIG. 3 to FIG. 18. The display device includes, but not limited to, a mobile phone, a tablet computer, a smartwatch, or the like. Because the foregoing display panel is used, the display device has a larger screen-to-body ratio.

FIG. 19 is a flowchart of a method for manufacturing a display panel according to some embodiments of the present disclosure. The method is used to manufacture any display panel shown in FIG. 3 to FIG. 18. As shown in FIG. 19, the manufacturing method includes the following processes.

In process S11, a to-be-cut display panel is provided.

The display panel includes a main body region 11, a first bonding region 121, and a to-be-removed region 13. The first bonding region 121 is connected to an edge of the main body region 11. The to-be-removed region 13 surrounds the main body region 11 and the first bonding region 121, and the to-be-removed region 13 is connected to the edge of the main body region 11 and an edge of the first bonding region 121.

In process S12, the to-be-removed region 13 is removed, and an inward concave notch 11a is formed on the edge of the main body region 11, wherein the first bonding region 121 is disposed in the notch 11a.

In some embodiments, the to-be-removed region 13 is removed through laser cutting, cutter cutting, or in another manner.

During a cutting process, the to-be-removed region 13 is removed. The notch 11a is formed at the edge of the main body region 11, and the first bonding region 121 is arranged in the notch 11a, such that the first bonding region 121 moves in the inward concaving direction of the edge of the main body region 11 by a distance. In the case that the first bonding region 121 is bent, the outward protruding distance of the first bonding region 121 relative to the edge, except the portion of the notch 11a, of the main body region 11 is reduced, or even the outward protruding distance of the first bonding region 11 is reduced to make the first bonding region 121 flush with the edge, except the portion of the notch 11a, of the main body region 11, thereby avoiding the impact of the protrusion of the first bonding region 121 on the subsequent processing of the display panel 1, and facilitating increasing the screen-to-body ratio of the display device.

In some embodiments, prior to cutting, a groove 102a is further formed at a surface, away from the panel body 101, of the back film 102. The groove 102a extends along at least a portion of the edge of the main body region 11, the groove 102a is at least partially disposed in the first bonding region 121, and a gap is provided between the groove 102a and the edge of the main body region 11.

For specific content about the groove 102a, reference is made to the description of the groove 102a above. Details are not described herein again.

The foregoing is merely optional embodiments of the present disclosure but is not used to limit the present disclosure. Any changes, equivalent substitutions, and improvements made within the concept and principle of the present disclosure shall fall within the protection scope of the present disclosure.

1. A display panel, comprising a main body region and a first bonding region, wherein an edge of the main body region is partially inward concaved to form a notch, and the first bonding region is disposed in the notch and is connected to the edge of the main body region.

2. The display panel according to claim 1, wherein a width of the notch gradually decreases in an inward concaving direction of the edge of the main body region.

3. The display panel according to claim 2, wherein the notch has a shape of a trapezoid.

4. The display panel according to claim 3, wherein the first bonding region is connected to a short base of the trapezoid.

5. The display panel according to claim 1, wherein the display panel comprises a plurality of the first bonding regions, and the edge of the main body region is provided with a plurality of the notches, the plurality of first bonding regions being respectively disposed in the plurality of notches.

6. The display panel according to claim 5, further comprising a panel body and a back film, wherein a surface of the panel body is attached to the back film, and a surface, away from the panel body, of the back film is provided with a groove, the groove extending along at least a portion of the edge of the main body region, and the groove being at least partially disposed in at least one of the plurality of first bonding regions.

7. The display panel according to claim 6, further comprising a to-be-removed region; wherein
the to-be-removed region surrounds the main body region and the first bonding region and is connected to the edge of the main body region and an edge of the first bonding region;
the groove extends into the to-be-removed region, and a gap is provided between the groove and the edge of the main body region.

8. The display panel according to claim 7, wherein the groove comprises a first sidewall close to the main body region and a second sidewall opposite to the first sidewall, wherein the first sidewall extends along a portion of the edge, at a side close to the groove, of the main body region.

9. The display panel according to claim 7, wherein in a length direction of the groove, a width of the groove at different positions are unchanged.

10. The display panel according to claim 7, wherein at least one end of the groove is disposed in at least one of the plurality of notches.

11. The display panel according to claim 7, wherein the back film is provided with a plurality of the grooves, wherein
the plurality of grooves are arranged in one-to-one correspondence to the plurality of first bonding regions.

12. The display panel according to claim 11, wherein the first bonding region is disposed at each of two opposite sides of the main body region.

13. The display panel according to claim 7, wherein the panel body is provided with an alignment mark disposed in the to-be-removed region; wherein
the alignment mark is disposed in the groove; or
the back film is further provided with an alignment slot formed in the to-be-removed region, and the alignment mark is disposed in the alignment slot.

14. The display panel according to claim 1, further comprising a second bonding region, wherein the second bonding region is disposed outside the notch and connected to the edge of the main body region.

15. The display panel according to claim 14, wherein the second bonding region and the first bonding region are disposed at two opposite sides of the main body region.

16. A method for manufacturing a display panel, comprising:
providing a to-be-cut display panel, wherein the display panel comprises a main body region, a first bonding region, and a to-be-removed region, the first bonding region being connected to an edge of the main body region, and the to-be-removed region surrounding the main body region and the first bonding region and being connected to the edge of the main body region and an edge of the first bonding region; and
removing the to-be-removed region, and forming an inward concave notch on the edge of the main body region, the first bonding region being disposed in the notch.

17. The method according to claim 16, wherein
the display panel comprises a panel body and a back film, a surface of the panel body is attached to the back film, and
prior to removing the to-be-removed region, the method further comprises:
forming a groove at a surface, away from the panel body, of the back film, wherein the groove extends along at least a portion of the edge of the main body region and is at least partially disposed in the first bonding region, and a gap is provided between the groove and the edge of the main body region.

18. A display device, comprising a display panel, wherein the display panel comprises a main body region and a first bonding region, wherein an edge of the main body region is partially inward concaved to form a notch, and the first bonding region is disposed in the notch and is connected to the edge of the main body region.

19. The display panel according to claim 7, wherein the back film is provided with a plurality of the grooves, wherein
at least one of the plurality of grooves is disposed in multiple of the plurality of first bonding regions.

20. The display panel according to claim 7, wherein the panel body is provided with an alignment mark disposed in the to-be-removed region, and the back film is further provided with an alignment slot formed in the to-be-removed region, the alignment mark being disposed in the alignment slot.
